(19) United States
(12) Patent Application Publication
(10) Pub. No.: US 2015/0364666 A1
(43) Pub. Date: Dec. 17, 2015

(54) REFRIGERATION POWER THERMOELECTRIC POWER GENERATION APPARATUS

(71) Applicant: NANJING RECLAIMER ENVIRONMENTAL TEKNIK CO., LTD., Nanjing, Jiangsu (CN)

(72) Inventor: Haibo WANG, Nanjing, Jiangsu (CN)

(21) Appl. No.: 14/763,718

(22) PCT Filed: Nov. 29, 2013
(86) PCT No.: PCT/CN2013/088174

§ 371 Date: Jul. 27, 2015

(30) Foreign Application Priority Data
Jan. 27, 2013 (CN) 201310030046.3

(51) Int. Cl. H01L 35/30; H01L 35/32

(52) U.S. Cl. CPC H01L 35/30; H01L 35/32

(57) ABSTRACT

This invention is about a cold energy thermoelectric power generation apparatus, which is based on thermoelectric couple assemblies with small temperature difference, so that thermoelectric couples function with light load and high efficiency, with greatly extended service life, furthermore, it is not necessary to use an air radiator or circulating cooling water system as in a traditional thermoelectric generator, therefore the flow setup is simpler; by using the cold recovery and circulation technology, the cold energy in the recovered liquefied gas can be used for power generation, the utilization rate of useful cold energy, or cold energy lian can be over 35%, and the equipment maintenance work quantity is substantially reduced as compared with a traditional thermoelectric generator, achieving quite significant economic, social, and environmental protection benefit, and it is a breakthrough to the traditional cold energy recovery technology.

### TECHNICAL FIELD

This invention is about a cold energy thermoelectric power generation apparatus, specifically it falls into the technical field of cryogenic cold energy recovery.

### BACKGROUND OF THE INVENTION

Gas products, as important basic raw materials in modern industries, have quite extensive applications, and are used in massive quantity in metallurgical, iron and steel, petroleum, chemical, machine building, electronic, glass, ceramics, building materials, construction, food processing and pharmaceutical and medical sectors. Because of the large coverage of applications of gas products, the production and supply of gases are taken as infrastructure for industrial investment environment together as power supply and water supply, and included in the utility sector as the “lifeline” of national economy.

To facilitate storage and transport in large quantity, gases are often liquefied into liquefied gases to increase the efficiency of transport and storage. When they are used, liquefied gases such as LNG, liquid nitrogen, liquid oxygen, liquid carbon dioxide and liquid ammonia are converted into gas at room temperature, and in this process, large amount of useful cold energy is released, however, at present, most of this cold energy is not effectively used, resulting in waste of large amount of precious resources. Take LNG as an example: presently in the world, most LNG cold energy consuming projects are single users, with only a very small number of multi-user integrated projects, today, only about 20% of the LNG cold energy can be used, and the quantity of cold energy used accounts for only about 8% of the total amount of LNG cold energy. In the current utilization technologies, except for air separation at a temperature of −145˜−75° C., the cold temperature level of other users does not match with the cold energy temperature distribution of LNG gasification, that is, “energy of high quality is used at low level”, with great loss of useful energy in processes.

At present, the cold energy in LNG is used mainly in the forms of direct use (cold energy power generation, air separation and refrigeration) and indirect use (cryogenic crushing, waste water and pollutant treatment, and so on). Most applications are in power generation with LNG cold energy, and the relevant technologies are fairly mature. The main advantages are on 4 aspects: first, it is conducive to optimizing and adjusting power source structure; second, it is conducive to mitigating environmental protection pressure; third, it can increase the energy utilization efficiency in power generation; and fourth, it can alleviate the pressure on grid power transmission and grid construction. However in essence, the cold energy power generation at present is only low quality utilization of cold energy.

It is expected that by the mid of this century, if China consumes natural gas of 5000*10⁸ m³/a, including import of LNG1000*10⁸ m³/a (equivalent the present import of Japan), the usable cold energy is 257*10⁸ kWh/a, equivalent to the annual power generation amount of a power plant of 600*10⁴ kW. Therefore, it is worth our in-depth consideration on how to realize breakthroughs in aspects of technology, management mechanism and market operation for utilization of LNG cold energy, to increase the LNG cold energy utilization rate to over 70% and the utilization of useful energy to over 40%, at the leading level in the world, push forward rapid development of large scale cold energy industrial chain including air separation and gasification of coal with enriched air for huge energy conservation and economic benefit, so as to make contribution to the full realization of cyclic economy and saving economy in China. In the meantime, the rapid development and transition of Chinese economy has determined the absolute necessity of large-scale use of LNG cold energy, and also provided a huge cold energy user market. The cold energy of large LNG terminals should first be aimed at large-scale markets of big air separation, coal gasification and light hydrocarbon separation. Traditional cold energy industry also requires integrated utilization in the cyclic economy pattern. It should be pointed out that, in addition to large LNG terminals, there will be several hundred small LNG satellite gasification stations for tank and box transport, and the HP natural gas pipe network covering the whole country to distribute LNG to MP and LP pipe networks of end users by using the energy of differential pressure, at which cold energy can be obtained with expander or gas wave refrigeration. These are all precious energy and wealth, with total cold energy no less than that in large LNG terminals, so they should be fully utilized by overall planning.

Large-scale comprehensive utilization of LNG cold energy has not been realized up to date mainly because of the technical obstacle that the gasification operation of LNG and the use of cold energy by downstream users are not synchronous in time and space. It is not synchronous in time because the load at a terminal must change according to downstream demand, with mainly seasonal and day and night fluctuations, and the cold energy load demand of cold energy users varies with production processes and market demand. The two are completely different, and basically not synchronous. It is not synchronous in space because for a terminal, it is only necessary to take into consideration jetty, LNG tanks and gasification facilities, and they do not require much land area, however, the downstream users for cold energy, either air and light hydrocarbon separation, or waste tyre cryogenic crushing, dry ice and refrigerating stores, all require large land areas, and the cold energy transport distance usually exceeds 1 km even if they are arranged as close to the terminal as possible. These lead to two questions: first, factors of safety and load regulation have determined that LNG gasification operation must be absolutely performed at the terminal, and it is not possible to arrange this operation at a number of cold energy users at long distances; second, the long distance transport of cold energy can result in considerable loss and quality deterioration of cold energy, reducing the economic efficiency. Large-scale comprehensive and full utilization of LNG cold energy can be possible only by solving these two big questions. Other liquefied gas products have the similar questions as LNG.

In 1821, German scientist Seebeck first found the thermoelectric phenomena, i.e. in an open circuit comprised of two different conductors, an electromotive force E₀ is produced in the open circuit if there is a temperature difference at the two junctions of the conductors, which is the Seebeck effect. The electromotive force produced by Seebeck effect is referred to as thermoelectro motive force. It is so called because people realized later on that the compass is deflected due to the current produced in a circuit by temperature difference.

About 12 years later, Peltier of France found that, when current flows through the interface of two different conductors, heat is obtained from the outside or released, which is the Peltier effect. The heat flow produced by Peltier effect is referred to as Peltier heat. However, he failed to realize the essence of his discovery and its relationship with the Seebeck effect. It was in 1838 that the essence of the Seebeck effect was first correctly interpreted by Lenz.

In 1855, Thomson found and established the relationship between Seebeck effect and Peltier effect, and predicted the existence of the third thermoelectric phenomenon, or the Thomson effect; later, he proved this effect with experiment. The relationship found by Thomson greatly promoted the subsequent development of thermoelectrics and thermodynamics.

In 1947, Tex successfully developed the first thermoelectric generator, but the power generation efficiency was only 1.5%. Later on, the demands for power source in military and space flight fields pushed forward the rapid development of thermoelectric generator.

In 1949, Loffe of the former USSR put forth the semiconductor thermoelectric theory, and also did a lot of work in its practical application, in 1953, a prototype of thermoelectric household refrigerator was developed, and in 1956, he published the book “Semiconductor Thermoelectric Elements and Thermoelectric Refrigeration”, marking the start of practical electrical appliance products based on the thermoelectric conversion effect, and it developed quite rapidly afterwards. However, the development was slow as compared with the development of other semiconductor elements. The biggest restricting factor in the application of thermoelectric conversion power is that the conversion efficiency is too low, incomparable with the traditional power converters, so the research fell into a valley for a time. However in 1959, Dr. Zener predicted that thermoelectric materials could realize performance similar to that of Freon compression refrigeration or turbo-generator, which undoubtedly was a cardiac stimulant and excitant to the industrialization of thermoelectric elements. In the early 1960s, about 100 specialized factories appeared all of a sudden, and this also greatly stimulated the enthusiasm of scientists to explore on basic theory and new materials to seek for materials with better quality and value. In-depth researches were conducted on pseudo-binary and pseudo-ternary alloys systems based on bismuth telluride (Bi2Te3). Even though, for decades, the performance of materials was improved quite slowly. Comparatively, the element manufacturing processes became daily complete, products have been standardized and formed series and production in large scale.

However, as a type of solid energy conversion element, it has incomparable advantages, and with the daily expansion and upgrading of application fields, the advantages of daily mature thermoelectric elements of all types have been attached increasing importance, and these elements have found applications in many fields. These features include free of motion parts and noise, easiness of miniaturization and control, high reliability and long service life, and high reliability is its main advantage, usually in design, it is not necessary to use heat transfer media of other forms, therefore avoiding problems of vibration, pressure and system sealing that are encountered in the manufacturing of many other equipment. In many applications where energy conversion efficiency is not the main factor to be considered, thermoelectric elements demonstrate irreplaceable advantages. Today with daily increasing calls for environmental protection, thermoelectric converting elements have attracted further attention for their non-pollution feature and their potential of using residual heat and renewable energy. At the end of the 20th century, the rapid development of high temperature superconducting materials with superconducting transition temperature above liquid nitrogen temperature and their applications could be said as one of the most important scientific and technological results, to meet the demand for cryogenic conditions with quite wide application prospectives in the future, in the research of thermoelectric refrigeration, obtaining such low temperature also became an important subject. This effort included further selection of possible materials.

It is regretful that the prediction by Zener has not yet realized up to date. And at present, it is difficult to determine if it can be realized, that is to say, in the pure viewpoint of energy conversion efficiency, thermoelectric cannot be compared with traditional methods.

The root cause of failure to achieve any major breakthrough is the absence of guidance by correct refrigeration theory and failure to realize that the high efficiency application field really suitable to the thermoelectric conversion apparatus is the low temperature field below ambient temperature, i.e. the field of conversion of cold energy to electric power, and the failure to find a high efficiency mode of cold energy power generation. If this question can be effectively solved, thermoelectric materials can fully realize performance similar to that of Freon compression refrigeration or turbo-generator and realize the prediction of Dr. Zener. This invention is theoretical and practical exploration of this question.

The traditional refrigerating theory is mainly based on thermodynamics, i.e. Carnot reverse cycle of identical temperature difference is used to analyze the refrigerating cycle process, the economic indicator of the refrigerating cycle is the refrigeration coefficient, or the ratio of obtained gain to the cost of consumption, and also, of all refrigerating cycles between atmospheric environment with temperature of T₀ and low temperature heat source with temperature of Tc (such as refrigeration store), the reverse Carnot cycle has the highest refrigeration coefficient:

$${ɛ}_{c} = {( COP )}_{R , C} = \frac{{q}_{2}}{{w}_{0}} = \frac{{T}_{c}}{{T}_{0} - {T}_{c}} \qquad ( 1 )$$

In the formula above, ε_{c} is the refrigeration coefficient, q₂ refrigerating capacity of the cycle, and w₀ the net power consumed by the cycle.

In fact, in his thesis “Reflections on the Motive Power of Heat”, Carnot concluded that: of all heat engines working between two constant temperature heat sources of different temperatures, the reversible heat engine has the highest efficiency.” This was later referred to as the Carnot theorem, after rearranging with the ideal gas state equation, the thermal efficiency of Carnot cycle obtained is:

$${η}_{c} = 1 - \frac{{T}_{2}}{{T}_{1}} \qquad ( 2 )$$

In Formula (2), temperature T₁ of the high temperature heat source and temperature T₂ of low temperature heat source are both higher than the atmosphere ambient temperature T₀, and the following important conclusions can be obtained:

1) The thermal efficiency of Carnot cycle only depends on the temperature of high temperature heat source and low temperature heat source, or the temperature at which the media absorbs heat and release heat, therefore the thermal efficiency can be increased by increasing T₁ and T₂.

2) The thermal efficiency of Carnot cycle can only be less than 1, and can never be equal to 1, because it is not possible to realize T₁=∞ or T₂=0. This means that a cyclic engine, even under an ideal condition, cannot convert all thermal energy into mechanical energy, of course, it is even less possible that the thermal efficiency is greater than 1.

3) When T₁=T₂, the thermal efficiency of the cycle is equal to 0, it indicates that in a system of balanced temperature, it is not possible to convert heat energy into mechanical energy, heat energy can produce power only with a certain temperature difference as a thermodynamic condition, therefore it has verified that it is not possible to build a machine to make continuous power with a single heat source, or the perpetual motion machine of the second kind does not exist.

4) Carnot cycle and its thermal efficiency formula are of important significance in the development of thermodynamics. First, it laid the theoretical foundation for the second law of thermodynamics; secondly, the research of Carnot cycle made clear the direction to raise the efficiency of various heat power engines, i.e. increasing the heat absorbing temperature of media and lowering the heat release temperature of media as much as possible, so that the heat is release at the lowest temperature that can be naturally obtained, or at the atmospheric temperature. The method mentioned in Carnot cycle to increase the gas heat absorbing temperature by adiabatic compression is still a general practice in heat engines with gas as media today.

5) The limit point of Carnot cycle is atmospheric ambient temperature, and for refrigerating process cycles below ambient temperature, Carnot cycle has provided no definite answer.

Because of the incompleteness of refrigeration coefficient, many scholars at home and abroad conducted research on it, and proposed methods to further improve it. In “Research on Energy Efficiency Standard of Refrigerating and Heat Pump Products and Analysis of Consummating Degree of Cyclic Thermodynamics”, Ma Yitai et al, in conjunction with the analysis of introduction of the irreversible process of thermodynamic heat transfer into heat cycle by Curzon and Ahlborn and the enlightenment from the finite time thermodynamics created on it, as well as the CA cycle efficiency, proposed the consummating degree of thermodynamics of CA normal circulation, advancing to a certain extent the energy efficiency research on the refrigerating and heat pump products.

However, the basic theory of thermodynamics cannot make simple, clear and intuitional explanation of the refrigerating cycle. Einstein commented the classical thermodynamics this way: “A theory will give deeper impression to the people with simpler prerequisite, more involvement and wider scope of application.” In the theoretical interpretation in the refrigeration field, this point should be inherited and carried forward.

Therefore, it has become a difficult issue in the research of field of refrigeration and cold energy recovery and thermoelectric technology to really find the correct theoretical foundation for refrigerating cycle, develop a new energy thermoelectric power generation circulation apparatus on this theoretical foundation and apply it in practice, effectively increase cold energy to power conversion efficiency and solve this world famous difficult issue of cold energy recovery.

### Content of the Invention

The purpose of this invention is, for making up the incompleteness of applying Carnot theorem to refrigeration and analysis of cold energy recovery and thermoelectric conversion theory, proposing a refrigerating theory corresponding to thermodynamic theory, or cold dynamics theory: any environment below the atmospheric ambient temperature is referred to as a cold source, corresponding to heat source above the ambient temperature; and corresponding to heat energy and heat, the corresponding concepts of cold energy and cold are proposed; Propose the formulas for energy conversion and conservation law in cold energy conversion, second law of cold dynamics, and cold useful energy analysis. Corresponding to the useful energy “Yong” and useless energy “Jin” of heat quantity, and with the meanings of heat for fire and cold for water, the useful energy of cold energy is named as “cold energy lian”, and the useless energy of cold energy transferred to the environment is named as “cold energy jin”, and this “jin” is to water.

In the refrigerating process, the transfer of cold energy follows the energy conversion and conservation law.

To describe the cold transfer direction, conditions and limit in the refrigerating process, the second law of cold dynamics is proposed: the essence of the second law of cold dynamics is identical to that of the second law of thermodynamics, and it also follows the “energy quality declining principle”, i.e. cold energy of different forms differs in “quality” in the ability to convert into power; and even the cold energy of the same form also has different ability of conversion at different status of existence. All actual processes of cold energy transfer are always in the direction of energy quality declination, and all cold energy spontaneously converts in the direction of atmospheric environment. The process to increase the quality of cold energy cannot perform automatically and independently, a process to increase energy quality is surely accompanied by another process of energy quality declination, and this energy quality declination process is the necessary compensating condition to realize the process to increase energy quality, that is, the process to increase energy quality is realized at the cost of energy quality declination as compensation. In the actual process, the energy quality declination process, as a cost, must be sufficient to compensate for the process to increase the energy quality, so as to meet the general law that the total energy quality must certainly decline. Therefore, with the given compensation condition for energy quality declination, the process to increase the energy quality surely has a highest theoretical limit. This theoretical limit can be reached only under the complete reversible ideal condition, in this case, the energy quality increase value is just equal to the compensation value for energy quality declination, so that the total energy quality remains unchanged. This shows that a reversible process is a pure and ideal process of energy quality conservation, in an irreversible process, the total energy quality must surely decline, and in no case it is possible to realize a process to increase the total energy quality in an isolated system. This is the physical connotation of the energy quality declining principle, the essence of the second law of cold dynamics, and also the essence of the second law of thermodynamics, and it reveals the objective law of the direction, conditions and limit of process that must be followed by all macroscopic processes.

The basic formula describing the second law of cold dynamics is:

$${η}_{c} = 1 - \frac{{T}_{c 2}}{{T}_{c 1}} \qquad ( 3 )$$

In Formula (3), Tc2<Tc1<T₀, T₀ is the ambient temperature, all based on Kelvin temperature scale.

With respect to the ambient temperature T₀, the maximum cold efficiency of the cold source at Tc1 and Tc2 is:

$$\begin{matrix}{η}_{c} = 1 - \frac{{T}_{c 1}}{{T}_{0}} & ( 4 ) \\ {η}_{c} = 1 - \frac{{T}_{c 2}}{{T}_{0}} & ( 5 )\end{matrix}$$

Suppose q₂ is the refrigerating capacity of the cycle, and w₀ the net power consumed by the cycle, then when the cold source temperature is Tc1:

$${w}_{0} = ( 1 - \frac{{T}_{c 1}}{{T}_{0}} ) {q}_{2} \qquad ( 6 )$$

Similarly, when the cold source temperature is Tc2:

$${w}_{0} = ( 1 - \frac{{T}_{c 2}}{{T}_{0}} ) {q}_{2} \qquad ( 7 )$$

It is not difficult to see from Formulas (4) to (7) that, the efficiency of the cold dynamics is between 0 and 1, and due to unavoidable irreversibility in the actual process, the refrigerating cycle efficiency is less than 1; when the ambient temperature T₀ is determined, the lower cold source temperature, the more refrigerating capacity can be obtained with the same amount of work input, and this has pointed out the direction for building new refrigerating cycle, or high efficiency electric power and cold energy conversion.

It should be noted that:

(1) The cold is transferred spontaneously from the cryogenic cold source to ambient temperature;

(2) It is not possible to transfer cold from a cryogenic cold source to a cold source of lower temperature without causing other change;

(3) When the cold is transferred from a cryogenic cold source to the environment, the power exchanged with the outside is w₀, which includes the useless work p₀(V₀−V_{c}) made to the environment, p₀ is the atmospheric pressure, V₀ the volume at ambient temperature, Vc the volume at cold source temperature, and the maximum reversible useful work made is:

$${( {W}_{u} )}_{max} = {W}_{0} - {p}_{0} ( {V}_{0} - {V}_{c} ) = ( 1 - \frac{Tc}{To} ) {Q}_{0} - {p}_{0} ( {V}_{0} - {V}_{c} )$$

(4) When the cold is transferred from a cryogenic cold source to the environment, the cold energy jin transferred to the environment is:

$${E}_{useless} = \frac{Tc}{To} {Q}_{0}$$

The useless work transferred to the environment is: p₀(V₀−V_{c})

(5) When cold energy is transferred to environment, the best form of making work to the outside is using a thermoelectric generator of Seebeck effect, or cold power generator; when electric energy is converted to cold energy, the best form of conversion is the thermoelectric refrigerator based on Peltier effect;

(6) In cold dynamics, the energy must and also inevitably follow the energy conversion and conservation law;

(7) With reference to the conception of finite time thermodynamics, it is possible to develop the basic theory of finite time cold dynamics;

(8) The quality of cold energy cannot be assessed by separating it from the specific environment.

(9) With reference to the analysis thinking of introduction of the irreversible process of thermodynamic heat transfer into heat cycle by Curzon and Ahlborn and the enlightenment from the finite time thermodynamics created on it, in conjunction with the CA cycle efficiency, and according to the principle of corresponding states, the improvement formula of finite time cold dynamics has been proposed:

$${η}_{c} = 1 - \sqrt{\frac{{T}_{c 1}}{{T}_{0}}}$$

For methane: its boiling point temperature under standard atmospheric pressure is 111.7° K, the ambient temperature is taken as 298° K, so its maximum useful energy of the corresponding cold energy or the efficiency of cold energy lian is:

$${η}_{c} = 1 - \frac{{T}_{c 1}}{{T}_{0}} = 1 - \frac{111.7}{298} = 0.6252$$

Calculate using the improved formula:

$${η}_{c} = 1 - \sqrt{\frac{{T}_{c 1}}{{T}_{0}}} = 1 - \sqrt{\frac{111.7}{298}} = 0.3878 ,$$

this value should be the value that can be realized for the efficiency in cold power generation. The calculated value of efficiency shows that the cold to power conversion efficiency of cold energy is actually not low.

It can be seen from the theoretical foundation above that, the supposed cold dynamics has a theoretical framework system symmetric to thermodynamics, so it complies with the basic principle of scientific aesthetics, or the principle of symmetricity.

On the basis of the basic principle as stated above, this invention has proposed a cold energy thermoelectric power generation apparatus different from a traditional one, by building a cold recovery cycle of the cold dynamic cycle circuit with reference to the heat recovery cycle theory in heat machine cycle, to realize high efficiency cold to power conversion of cold energy, and recover the cold energy lian in the cold energy at a high efficiency; by means of an apparatus that can realize high efficiency conversion of useful energy to cold energy, the proposed theory can become a preliminarily completed closed-loop system that can really guide the practice.

The purpose of this invention is realized with the following measures:

A cold energy thermoelectric power generation apparatus, consisting of a cold energy thermoelectric power generation apparatus and a cold recovery apparatus, with the features that:

The liquefied gas 2 coming out from liquefied gas tank 1, is sent via hydraulic pump 3 into the cold energy thermoelectric power generation apparatus 4, through the cold energy recovery channel 4-2, the cold energy is converted into electric energy by the thermoelectric couple assembly 4-1, the unconverted cold energy is transferred to the gas at higher temperature from the cold recovery pipeline 7, the gas at increased temperature after releasing cold energy is sent via the gas supply pipeline 5 to gas consuming system 6; the gas diverted from the gas supply pipeline 5, after its pressure and temperature has been increased in cold recovery pipeline 7 and gas compressor 8, enters as cold recovery media the cold recovery channel 4-3 of cold energy thermoelectric power generation apparatus 4, to recover cold energy and reduce temperature, it also flows via the cold energy thermoelectric power generation apparatus 4 to become liquefied gas, and returns via throttle valve 12 to the liquefied gas tank 1; the DC power produced by the thermoelectric couple assembly is output by the DC power conversion and output apparatus 4-4, so as to realize the high efficiency recovery and utilization of cold energy from externally supplied liquefied gas.

When a closed-loop circulation is adopted for the liquefied gas: the liquefied gas 1 coming out from liquefied gas tank 2, is sent by hydraulic pump 3 into the cold energy recovery channel 4-2 of the cold energy thermoelectric power generation apparatus 4, the cold energy is converted into electric energy by thermoelectric couple assembly 4-1, the unconverted cold energy is transferred to the gas at higher temperature from the back flow pipeline 9, the gas at increased temperature after releasing cold energy is sent via gas supply pipeline 5 to the gas consuming system 6; the gas coming out from gas consuming system 6 flows via the back flow pipeline 9, thermostat 10 and gas compressor 8 into the cold recovery channel 4-3 of cold energy thermoelectric power generation apparatus 4, to recover cold energy and reduce temperature, and via cold energy thermoelectric power generation apparatus 4 to become liquefied gas, and returns to the liquefied gas tank (1) via throttle valve 12; the DC power produced by the thermoelectric couple assembly is output by the DC power conversion and output apparatus 4-4, so as to realize the high efficiency recovery and utilization of cold energy from externally supplied liquefied gas.

It is provided with the condensing evaporator 11: the liquefied gas 2 coming out from liquefied gas tank 1, is sent via hydraulic pump 3 and condensing evaporator 11 into the cold energy thermoelectric power generation apparatus 4, through the cold energy recovery channel 4-2, the cold energy is converted into electric energy by the thermoelectric couple assembly 4-1, the unconverted cold energy is transferred to the gas at higher temperature from the cold recovery pipeline 7, the gas at increased temperature after releasing cold energy is sent via the gas supply pipeline 5 to gas consuming system 6; the gas diverted from the gas supply pipeline 5, after its pressure and temperature has been increased in cold recovery pipeline 7 and gas compressor 8, enters as cold recovery media the cold recovery channel 4-3 of cold energy thermoelectric power generation apparatus 4, to recover cold energy and reduce temperature, it also flows via the cold energy thermoelectric power generation apparatus 4 and condensing evaporator 11 to become liquefied gas, and returns to the liquefied gas tank 1 via throttle valve 12; the DC power produced by the thermoelectric couple assembly is output by the DC power conversion and output apparatus 4-4, so as to realize the high efficiency recovery and utilization of cold energy from externally supplied liquefied gas.

Or the liquefied gas 2 coming out from liquefied gas tank 1, is sent by hydraulic pump 3 and condensing evaporator 11 into the cold energy recovery channel 4-2 of the cold energy thermoelectric power generation apparatus 4, the cold energy is converted into electric energy by thermoelectric couple assembly 4-1, the unconverted cold energy is transferred to the gas at higher temperature from the back flow pipeline 9, the gas at increased temperature after releasing cold energy is sent via gas supply pipeline 5 to the gas consuming system 6; the gas coming out from gas consuming system 6 flows via the back flow pipeline 9, thermostat 10 and gas compressor 8 into the cold recovery channel 4-3 of cold energy thermoelectric power generation apparatus 4, to recover cold energy and reduce temperature, and via cold energy thermoelectric power generation apparatus 4 and condensing evaporator 11 to become liquefied gas, and returns to the liquefied gas tank 1 via throttle valve 12; the DC power produced by the thermoelectric couple assembly is output by the DC power conversion and output apparatus 4-4, so as to realize the high efficiency recovery and utilization of cold energy from externally supplied liquefied gas.

The said cold energy thermoelectric power generation apparatus is comprised of the thermoelectric couple assembly 4-1, cold energy recovery channel 4-2, return passage 4-3 and DC power conversion and output apparatus 4-4.

The said thermoelectric couple assembly 4-1 is formed with one or a number of assemblies connected in a serial, parallel or serial-parallel pattern; each assembly of thermoelectric couples consists of multi-stage thermoelectric couples, connected in a serial, parallel or serial-parallel pattern.

A serial multi-stage thermoelectric couple has the feature that the working current of all stages is identical, and at the joint of stages, an electrically insulated cold conducting layer is required (normally they are separated by anodized aluminum oxide or two mutually parallel ceramic chips electrically insulated and with good cold conducting performance), it is required that the cold conducting layer has a high cold conducting coefficient, so as to reduce differential temperature loss; in the current passage, all thermoelectric couples are connected in series, and in cold energy passage, all thermoelectric couples are connected in parallel.

A parallel multi-stage thermoelectric couple features high working current, moreover, as both cold conducting and current conducting are required between stages, no electrical insulation layer is needed, and there is no temperature difference between stages. For the same temperature difference and load as those with a serial thermoelectric couple assembly, a parallel type consumes less power than a serial type, but with more complicated circuit design.

Each thermoelectric couple consists of a type P thermoelectric element and a type N thermoelectric element connected together, when there is a temperature difference between two fluids: the cold energy in the fluid at a lower temperature is transferred to the fluid at higher temperature, the current in the thermoelectric couple is P→N, so that the temperature of the fluid at lower temperature rises, and the fluid of the other side at higher temperature obtains cold energy and its temperature is lowered.

For type P, pseudo-ternary materials such as bismuth telluride-antimony telluride solid solution alloy or type P superconducting material can be selected; for type N, bismuth telluride-bismuth selenide solid solution alloy or type N superconducting material can be selected. If in type P, the third element bismuth selenide is added to the pseudo-binary system bismuth telluride-antimony telluride, the type N material can be binary solid solution, and that with a weight ratio of 93% bismuth telluride+7% bismuth selenide can be used.

High efficiency thermoelectric couples matching with the temperature variation interval should be selected according to different temperature zone.

FIG. 1 presents the sectional structure schematic diagram of a single stage thermoelectric generator, in which: 1—the side at higher temperature, 2—output, 3—the side at lower temperature; FIG. 2 presents the structure schematic diagram of two types of thermoelectric generators, FIG. 2(a) is a thermoelectric couple with parallel stages, FIG. 2(b) is a thermoelectric couple with serial stages; FIG. 3 is the structure schematic diagram of a thermoelectric generator, in which: 1—heat source, 2—thermoelectric module, 3—insulation layer, 4—radiator, 5—DC-DC converter; FIG. 4 is a process schematic diagram of a cold energy thermoelectric power generation apparatus of this invention; in FIG. 4: 1—liquefied gas tank, 2—liquefied gas, 3—hydraulic pump, 3-1—throttle valve, 3-2—cold energy thermoelectric power generation apparatus inlet pipeline, 4—cold energy thermoelectric power generation apparatus, 4-1—thermoelectric couple assembly, 4-2—cold energy recovery channel, 4-3—cold recovery channel, 4-4—DC power conversion and output apparatus, 5—gas supply pipeline, 6—gas consuming system, 7—cold recovery pipeline, 8—gas compressor, 9—back flow pipeline, 10—thermostat, 11—condensing evaporator, 12—throttle valve.

Whether serial or serial and parallel mode is used for the thermoelectric couple depends on the specific conditions of loads, in the practical application, only when the load resistance matches with the internal resistance of the thermoelectric generator by the combination of serial and parallel modes, can the maximum output power be obtained. For a thermoelectric generator formed by mutual serial connection of n pairs of thermoelectric couples, the open voltage V_{∝} at its output side is:

V_{∝}=n(aₓ−aₚ)(T₁−T₂)

In the case above, the voltage actually applied across the load is half of the open circuit voltage given by the formula above. This shows that the actual output voltage of the generator is related to the number of thermoelectric couples. For applications with high output power, the demand can be met by using a fairly large number of thermoelectric couples, therefore it is not difficult to obtain a high output voltage. However, for cases requiring low output power, the power demand can be met by connecting a small number of thermoelectric couples in series, and the result is that the output voltage to meet the power demand may be quite low. On the other hand, most electronic devices usually require an input voltage at the volt magnitude, which makes it difficult for the output voltage of low power thermoelectric generators to directly meet the application requirement. Therefore, it is necessary to convert the “high” current and “low” voltage output from thermoelectric generators into “low” current and “high” voltage output, and this requires using a DC-DC converter. Usually, the conversion efficiency of voltage is irrelevant with output power, and is a function of the generator output voltage, in practical applications, it is alright to ensure a conversion efficiency of over 60%, and in this case, the corresponding lower limit voltage is only about 0.2V.

The said cold energy recovery channel and return passage are hollow circular, rectangular or curved cavities; the said cold energy recovery channel and return passage are provided with necessary enhanced heat transfer means, such as more fins, and the use of plate-fin heat exchanger, micro channel heat exchanger and so on.

For the cold energy thermoelectric power generation apparatus of this invention, other structures not mentioned in the thermoelectric couple assembly will not be described in detail, for the thermoelectric power generation module, no schematic diagram of detailed structure and their associated facility is presented, and they will all be designed with the existing mature technologies for thermoelectric generators.

The said cold energy recovery channel 4-2, return passage 4-3 are made of plate-fin cold exchange elements, micro channel cold exchange elements or other types of enhanced cold transfer elements, their structures are identical or similar to the heat transfer elements in traditional refrigerating cycles, and the enhanced heat transfer technology of parallel flow evaporator in automobile air conditioners can also be referenced.

The said liquefied gas tank 1 is provided with necessary thermal and cold insulation, such as thermal isolated vacuum container, and insulation materials such as pearlite.

The equipment and their backup systems, pipes, instruments, valves, cold insulation and bypass facilities with regulation functions not described in this invention shall be configured with generally known mature technologies.

Safety and regulation and control facilities associated with the cold energy thermoelectric power generation apparatus of this invention are provided, so that the apparatus can operate economically and safely with high thermal efficiency, to achieve the goal of energy conservation, consumption reduction and environmental protection.

This invention has the following advantages as compared with existing technologies:

1. Substantial energy conservation effect: The cold energy of liquefied gas recovered efficiently by the technology of cold recovery cycle can be used to efficiently generate thermoelectric power, which can effectively increase the thermoelectric conversion efficiency, and the utilization rate of cold energy lian can be over 35%, achieving quite significant economic, social, and environmental protection benefit, and it is a breakthrough to the traditional cold energy recovery technology.

2. It requires no air radiator or circulating cooling water system as in a traditional thermoelectric generator, so the process flow setup is simpler and better complies with the principle of energy conservation and environmental protection.

3. The equipment maintenance work quantity is greatly reduced as compared with a traditional thermoelectric generator, and it is based on thermoelectric couple assemblies with small temperature difference, so that thermoelectric couples function with light load and high efficiency, with greatly extended service life.

4. Enhanced cold transfer: as compared with a traditional thermoelectric generator based on air cooling or water cooling for heat or cold dissipation, this invention adopts the cold recovery cycle technology to recover at high efficiency the cold energy through the thermoelectric generator, also, enhanced cold transfer elements can be used conveniently, so that the thermoelectric power generation apparatus can be more compact with higher power generation efficiency.

### DESCRIPTION OF FIGURES

FIG. 1 is the sectional structure schematic diagram of a single-stage thermoelectric generator.

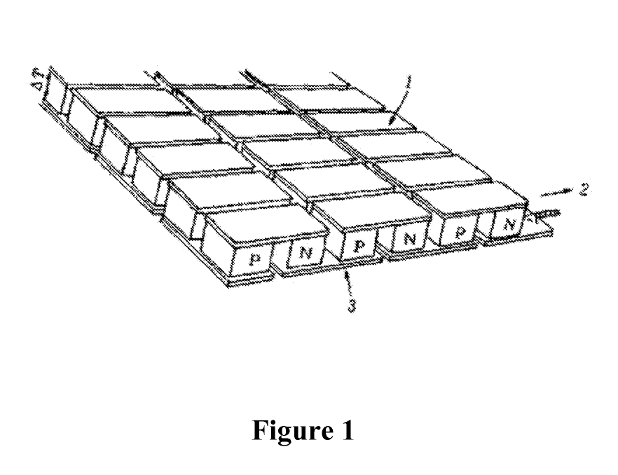

In FIG. 1: 1—the side at higher temperature, 2—output, 3—the side at lower temperature.

FIG. 2 is the structure schematic diagram of two types of thermoelectric generators, FIG. 2(a) is a thermoelectric couple with parallel stages, and FIG. 2(b) is a thermoelectric couple serial stages:

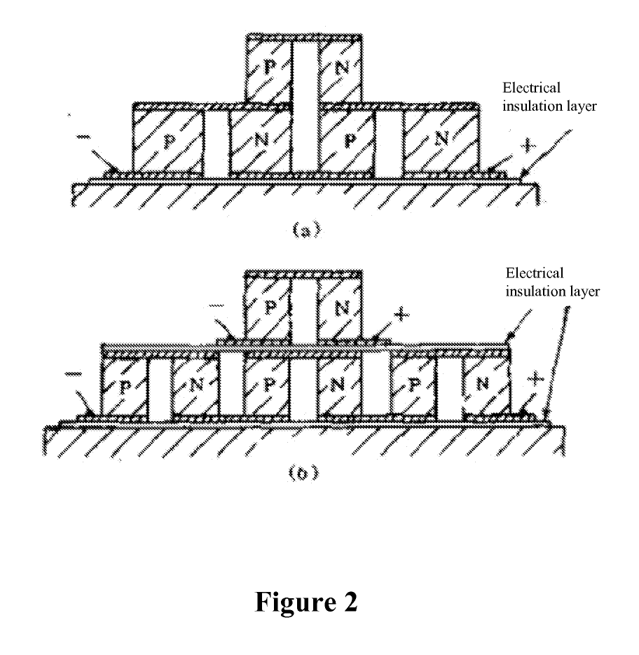

FIG. 3 is the structure schematic diagram of a thermoelectric generator:

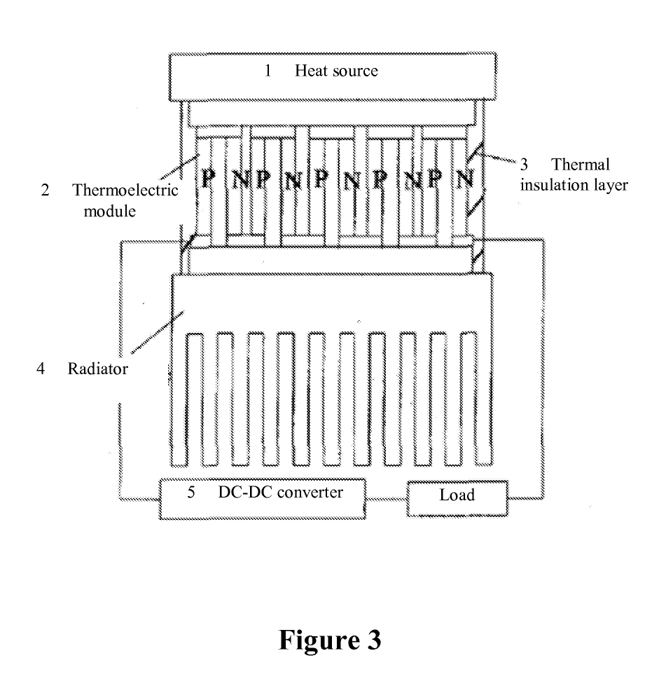

In FIG. 3: 1—heat source, 2—thermoelectric module, 3—insulation layer, 4-radiator, 5—DC-DC converter.

FIG. 4 is a process schematic diagram of a cold energy thermoelectric power generation apparatus of this invention:

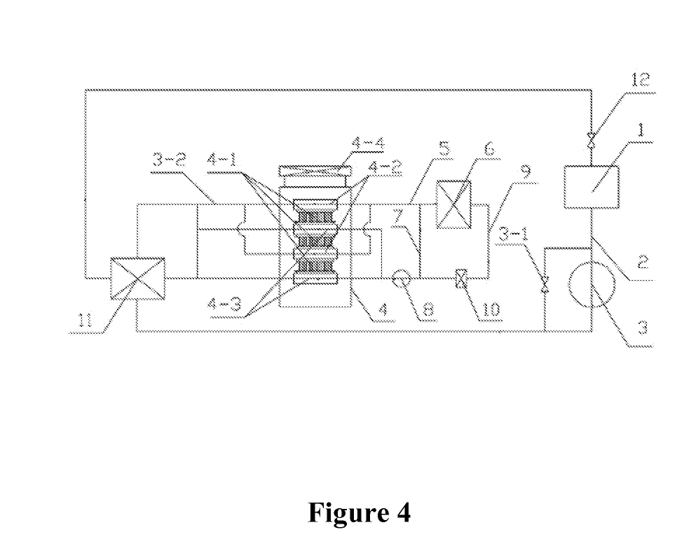

In FIG. 4: 1—liquefied gas tank, 2—liquefied gas, 3—hydraulic pump, 3-1—throttle valve, 3-2—cold energy thermoelectric power generation apparatus inlet pipeline, 4—cold energy thermoelectric power generation apparatus, 4-1—thermoelectric couple assembly, 4-2—cold energy recovery channel, 4-3—cold recovery channel, 4-4—DC power conversion and output apparatus, 5—gas supply pipeline, 6—gas consuming system, 7—cold recovery pipeline, 8—gas compressor, 9—back flow pipeline, 10—thermostat, 11—condensing evaporator, 12—throttle valve.

### EMBODIMENTS

In the following, this invention is further described in detail in conjunction with figures and embodiments.

### Embodiment 1

A cold energy thermoelectric power generation apparatus as shown in FIG. 4, consisting of a cold energy thermoelectric power generation apparatus and a cold recovery apparatus, with the embodiment that:

The liquefied gas 2 coming out from liquefied gas tank 1, is sent via hydraulic pump 3 into the cold energy thermoelectric power generation apparatus 4, through the cold energy recovery channel 4-2, the cold energy is converted into electric energy by the thermoelectric couple assembly 4-1, the unconverted cold energy is transferred to the gas at higher temperature from the cold recovery pipeline 7, the gas at increased temperature after releasing cold energy is sent via the gas supply pipeline 5 to gas consuming system 6; the gas diverted from the gas supply pipeline 5, after its pressure and temperature has been increased in cold recovery pipeline 7 and gas compressor 8, enters as cold recovery media the cold recovery channel 4-3 of cold energy thermoelectric power generation apparatus 4, to recover cold energy and reduce temperature, it also flows via the cold energy thermoelectric power generation apparatus 4 to become liquefied gas, and returns to the liquefied gas tank 1; the DC power produced by the thermoelectric couple assembly is output by the DC power conversion and output apparatus 4-4, so as to realize the high efficiency recovery and utilization of cold energy from externally supplied liquefied gas.

The said cold energy thermoelectric power generation apparatus is comprised of the thermoelectric couple assembly 4-1, cold energy recovery channel 4-2, return passage 4-3 and DC power conversion and output apparatus 4-4.

The said thermoelectric couple assembly 4-1 is formed with one or a number of assemblies connected in a serial, parallel or serial-parallel pattern; each assembly of thermoelectric couples consists of multi-stage thermoelectric couples, connected in a serial, parallel or serial-parallel pattern.

This invention has been made public with an optimum embodiment as above, however, it is not used to restrict this invention, all variations or decorations made by those familiar with this technology without deviating from the spirit and scope of this invention also falls into the scope of protection of this invention. Therefore, the scope of protection of this invention shall be that defined by the claims in this application.

1. A cold energy thermoelectric power generation apparatus, consisting of a cold energy thermoelectric power generation apparatus and a cold recovery apparatus, with the features that:
The liquefied gas (2) coming out from liquefied gas tank (1), via hydraulic pump (3) or throttle valve (3-1), is sent into the cold energy thermoelectric power generation apparatus (4), the thermoelectric couple assembly (4-1) converts the cold energy released from the liquefied gas (2) in the cold energy recovery channel (4-2) into electric energy, the unconverted cold energy is transferred to the gas at high temperature from the cold recovery pipeline (7), the gas at increased temperature after releasing cold energy is sent via gas supply pipeline (5) to the gas consuming system (6); the gas diverted from the supply pipeline (5), after its pressure and temperature has been increased in the cold recovery pipeline (7) and gas compressor (8), enters as cold recovery media the cold recovery channel (4-3) of the cold energy thermoelectric power generation apparatus (4), flows via the cold energy thermoelectric power generation apparatus (4) to become the liquefied gas or gas, and returns to the liquefied gas tank (1) or cold energy thermoelectric power generation apparatus inlet pipeline (3-2); the DC power produced by thermoelectric couple assembly (4-1) is output by the DC power conversion and output apparatus (4-4), so as to realize high efficiency recovery and utilization of cold energy from liquefied gas;
Or the liquefied gas (2) coming out from liquefied gas tank (1), via hydraulic pump (3) or throttle valve (3-1), is sent into the cold energy recovery channel (4-2) of the cold energy thermoelectric power generation apparatus (4), to convert the cold energy into electric energy by the thermoelectric couple assembly (4-1), the unconverted cold energy is transferred to the gas at higher temperature from the back flow pipeline (9), the gas at increased temperature after releasing cold energy is sent via the gas supply pipeline (5) to gas consuming system (6); the gas flowing out from the gas consuming system (6), via the back flow pipeline (9) and gas compressor (8), enters the cold recovery channel (4-3) of cold energy thermoelectric power generation apparatus (4), flows through the cold energy thermoelectric power generation apparatus (4) to become liquefied gas or gas, and returns to the liquefied gas tank (1) or cold energy thermoelectric power generation apparatus inlet pipeline (3-2); the DC power produced by the thermoelectric couple assembly is output by the DC power conversion and output apparatus (4-4), so as to realize the high efficiency recovery and utilization of cold energy from externally supplied liquefied gas.

2. The apparatus as described in claim 1, with the features that:
It is provided with the thermostat (10): the liquefied gas (2) coming out from liquefied gas tank (1), is boosted by hydraulic pump (3) and sent into the cold energy recovery channel (4-2) of the cold energy thermoelectric power generation apparatus (4), the cold energy is converted into electric energy by thermoelectric couple assembly (4-1), the unconverted cold energy is transferred to the gas at higher temperature from the back flow pipeline (9), the gas at increased temperature after releasing cold energy is sent via gas supply pipeline (5) to the gas consuming system (6); the gas coming out from gas consuming system (6) flows via the back flow pipeline (9), thermostat (10) and gas compressor (8) into the cold recovery channel (4-3) of cold energy thermoelectric power generation apparatus (4), and via cold energy thermoelectric power generation apparatus (4) to become liquefied gas, and returns to the liquefied gas tank (1); the DC power produced by the thermoelectric couple assembly is output by the DC power conversion and output apparatus (4-4), so as to realize the high efficiency recovery and utilization of cold energy from externally supplied liquefied gas.

3. The apparatus as described in claim 2, with the features that:
It is provided with the condensing evaporator (11): the liquefied gas (2) coming out from liquefied gas tank (1), is sent via hydraulic pump (3) and condensing evaporator (11) into the cold energy thermoelectric power generation apparatus (4), through the cold energy recovery channel (4-2), the cold energy is converted into electric energy by the thermoelectric couple assembly (4-1), the unconverted cold energy is transferred to the gas at higher temperature from the cold recovery pipeline (7), the gas at increased temperature after releasing cold energy is sent via the gas supply pipeline (5) to gas consuming system (6); the gas diverted from the gas supply pipeline (5), after its pressure and temperature has been increased in cold recovery pipeline (7) and gas compressor (8), enters as cold recovery media the cold recovery channel (4-3) of cold energy thermoelectric power generation apparatus (4), to recover cold energy and reduce temperature, it also flows via the cold energy thermoelectric power generation apparatus (4) and condensing evaporator (11) to become liquefied gas, and returns to the liquefied gas tank (1); the DC power produced by the thermoelectric couple assembly is output by the DC power conversion and output apparatus (4-4), so as to realize the high efficiency recovery and utilization of cold energy from externally supplied liquefied gas;
Or the liquefied gas (2) coming out from liquefied gas tank (1), is sent by hydraulic pump (3) and condensing evaporator (11) into the cold energy recovery channel (4-2) of the cold energy thermoelectric power generation apparatus (4), the cold energy is converted into electric energy by thermoelectric couple assembly (4-1), the unconverted cold energy is transferred to the gas at higher temperature from the back flow pipeline (9), the gas at increased temperature after releasing cold energy is sent via gas supply pipeline (5) to the gas consuming system (6); the gas coming out from gas consuming system (6) flows via the back flow pipeline (9), or/and thermostat (10) and gas compressor (8) into the cold recovery channel (4-3) of cold energy thermoelectric power generation apparatus (4), to recover cold energy and reduce temperature, and via cold energy thermoelectric power generation apparatus (4) and condensing evaporator (11) to become liquefied gas, and returns to the liquefied gas tank (1); the DC power produced by the thermoelectric couple assembly is output by the DC power conversion and output apparatus (4-4), so as to realize the high efficiency recovery and utilization of cold energy from externally supplied liquefied gas

4. The apparatus as described in claim 3, with the features that:
It is provided with throttle valve (12): the cold recovery fluid diverted from gas supply pipeline (5), after boosting and increasing temperature in the cold recovery pipeline (7), gas compressor (8), or /and condensing evaporator (11), enters as cold recovery media the cold recovery channel (4-3) of the cold energy thermoelectric power generation apparatus (4), flows via the cold energy thermoelectric power generation apparatus (4) to become liquefied gas, and returns via throttle valve (12) to the liquefied gas tank (1); the DC power produced by thermoelectric couple assembly (4-1) is output by the DC power conversion and output apparatus (4-4), so as to realize the high efficiency recovery and utilization of cold energy from externally supplied liquefied gas; or the gas coming out from gas consuming system (6) enters via the back flow pipeline (9), or/and thermostat (10), gas compressor (8) into the cold recovery channel (4-3) of the cold energy thermoelectric power generation apparatus (4), and flows via cold energy thermoelectric power generation apparatus (4) to become liquefied gas, and returns via throttle valve (12) to the liquefied gas tank (1); the DC power produced by the thermoelectric couple assembly is output by the DC power conversion and output apparatus (4-4), so as to realize the high efficiency recovery and utilization of cold energy from externally supplied liquefied gas.

5. The apparatus as described in claim 1, with the features that:
The said cold energy thermoelectric power generation apparatus is comprised of the thermoelectric couple assembly (4-1), cold energy recovery channel (4-2), return passage (4-3) and DC power conversion and output apparatus (4-4).

6. The apparatus as described in claim 5, with the features that:
The said thermoelectric couple assembly (4-1) is formed with one or a number of assemblies connected in a serial, parallel or serial-parallel pattern; each assembly of thermoelectric couples consisting of multi-stage thermoelectric couples, connected in a serial, parallel or serial-parallel pattern.

7. The apparatus as described in claim 6, with the features that:
There can be one or a number of the said cold energy thermoelectric power generation apparatuses, connected in a serial, parallel or parallel serial pattern.

8. The apparatus as described in claim 1, with the features that:
There can be one or a number of the said cold energy thermoelectric power generation apparatuses, connected in a serial, parallel or parallel serial pattern.

9. The apparatus as described in claim 2, with the features that:
The said cold energy thermoelectric power generation apparatus is comprised of the thermoelectric couple assembly (4-1), cold energy recovery channel (4-2), return passage (4-3) and DC power conversion and output apparatus (4-4).

10. The apparatus as described in claim 3, with the features that:
The said cold energy thermoelectric power generation apparatus is comprised of the thermoelectric couple assembly (4-1), cold energy recovery channel (4-2), return passage (4-3) and DC power conversion and output apparatus (4-4).

11. The apparatus as described in claim 4, with the features that:
The said cold energy thermoelectric power generation apparatus is comprised of the thermoelectric couple assembly (4-1), cold energy recovery channel (4-2), return passage (4-3) and DC power conversion and output apparatus (4-4).

12. The apparatus as described in claim 2, with the features that:
There can be one or a number of the said cold energy thermoelectric power generation apparatuses, connected in a serial, parallel or parallel serial pattern.

13. The apparatus as described in claim 3, with the features that:
There can be one or a number of the said cold energy thermoelectric power generation apparatuses, connected in a serial, parallel or parallel serial pattern.

14. The apparatus as described in claim 4, with the features that:
There can be one or a number of the said cold energy thermoelectric power generation apparatuses, connected in a serial, parallel or parallel serial pattern.
